(19) United States
(12) Patent Application Publication
(10) Pub. No.: US 2025/0391777 A1
(43) Pub. Date: Dec. 25, 2025

(54) SEMICONDUCTOR DEVICE

(71) Applicant: Kioxia Corporation, Tokyo (JP)

(72) Inventors: Masayuki KITAMURA, Kawasaki Kanagawa (JP); Yasuo OTSUKA, Kawasaki Kanagawa (JP)

(21) Appl. No.: 19/058,209

(22) Filed: Feb. 20, 2025

(30) Foreign Application Priority Data
Jun. 20, 2024 (JP) 2024-099407

(51) Int. Cl. H01L 23/538; H01L 21/48; H01L 23/00; H01L 25/16; H05K 1/02; H05K 1/05; H05K 1/18; H10B 80/00; H10D 80/30

(52) U.S. Cl. CPC H01L 23/5383; H01L 23/5386; H01L 25/16; H01L 21/4857; H01L 24/16; H01L 24/48; H01L 24/73; H01L 2224/16225; H01L 2224/48147; H01L 2224/48225; H01L 2224/73257; H01L 2225/06506; H01L 2225/0651; H01L 2225/06517; H01L 2225/06562; H01L 2924/1431; H01L 2924/1438; H05K 1/0298; H05K 1/053; H05K 1/181; H10B 80/00; H10D 80/30

(57) ABSTRACT

A semiconductor device includes a first semiconductor module and a second semiconductor module; a wiring substrate including the first and the second semiconductor modules mounted on a first surface, a first signal line connecting a first electrode provided on a second surface to the first semiconductor module, a second signal line connecting a second electrode provided on the second surface to the second semiconductor module, a third signal line connected to the first signal line, and a fourth signal line connected to the second signal line; and a crosslinking wiring that connects end portions of the third and the fourth signal lines to each other. A first signal is input to and output from at least one of the first semiconductor module or the second semiconductor module through the first and second signal lines.

### CROSS-REFERENCE TO RELATED APPLICATION

This application is based upon and claims the benefit of priority from Japanese Patent Application No. 2024-099407, filed Jun. 20, 2024, the entire contents of which are incorporated herein by reference.

### FIELD

Embodiments described herein relate generally to a semiconductor device.

### BACKGROUND

A semiconductor system in which a plurality of semiconductor devices are mounted on a mounting substrate. A plurality of semiconductor modules in which semiconductor chips are stacked may be packaged in the semiconductor device. Various signals are input and output to each of the plurality of semiconductor modules through the mounting substrate.

Depending on the application of the product, a signal line transmitting the same signal may be shared between the plurality of semiconductor modules, and a signal line may be individually connected to each of the plurality of semiconductor modules. Therefore, it is necessary to change the wiring design of the semiconductor system for each application.

### DESCRIPTION OF THE DRAWINGS

FIGS. 1A and 1B are schematic diagrams showing an example of a configuration of a semiconductor system according to Embodiment 1.

FIGS. 2A and 2B are views showing a detailed configuration of a semiconductor device according to Embodiment 1.

FIGS. 3A to 3D are views sequentially showing a part of a procedure of a method of manufacturing the semiconductor device according to Embodiment 1.

FIGS. 4A and 4B are views showing a detailed configuration of the semiconductor device according to Embodiment 1, and are views showing the state after being diverted from a first specification to a second specification.

FIGS. 5A and 5B are views showing a semiconductor system according to a comparative example.

FIG. 6 is a view showing Modification Example 1 according to Embodiment 1.

FIG. 7 is a view showing Modification Example 2 according to Embodiment 1.

FIG. 8 is a schematic diagram showing an example of a configuration of a semiconductor system according to Embodiment 2.

FIGS. 9A and 9B are views showing a detailed configuration of a semiconductor device according to Embodiment 2.

FIGS. 10A to 10D are views sequentially showing a part of a procedure of a method of manufacturing the semiconductor device according to Embodiment 2.

FIGS. 11A and 11B are views showing a detailed configuration of the semiconductor device according to Embodiment 2, and are views showing the state after being diverted from a second specification to a first specification.

FIGS. 12A and 12B are views showing a modification example according to Embodiment 2.

FIGS. 13A and 13B are views showing a modification example according to Embodiment 2.

FIGS. 14A and 14B are views showing another modification example.

### DETAILED DESCRIPTION

Embodiments provide a semiconductor device that can generalize wiring design of a semiconductor system.

In general, according to one embodiment, a semiconductor device includes a first semiconductor module and a second semiconductor module each having one or more semiconductor chips stacked; a wiring substrate including the first and the second semiconductor modules mounted on a first surface, a first signal line connecting a first electrode provided on a second surface opposite to the first surface to the first semiconductor module, a second signal line connecting a second electrode provided on the second surface to the second semiconductor module, a third signal line connected to the first signal line and having an end portion exposed to a third surface, and a fourth signal line connected to the second signal line and having an end portion exposed to the third surface; and a crosslinking wiring that connects the end portions of the third and the fourth signal lines to each other. A first signal is input to and output from at least one of the first semiconductor module or the second semiconductor module through the first and second signal lines.

Hereinafter, embodiments will be described in detail with reference to the drawings. The present disclosure is not limited to the following embodiments. In addition, elements in the following embodiments include those that can be easily assumed by those skilled in the art or those that are substantially the same.

### Embodiment 1

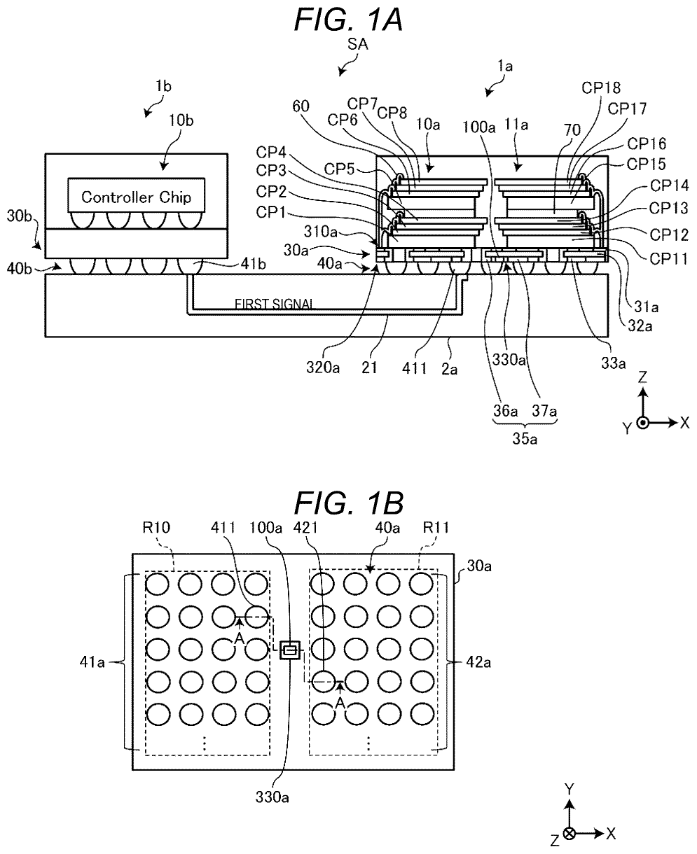

Hereinafter, Embodiment 1 of the present disclosure will be described in detail with reference to FIGS. 1A to 4B.

### Configuration Example of Semiconductor Device

FIGS. 1A and 1B are schematic diagrams showing an example of a configuration of a semiconductor system SA according to Embodiment 1. More specifically, FIG. 1A is a cross-sectional view taken along the XZ direction of the semiconductor system SA, and FIG. 1B is a plan view when the semiconductor device 1a provided in the semiconductor system SA is viewed from the negative Z direction (lower surface side of the semiconductor device 1a).

Meanwhile, in FIG. 1A, hatching is omitted in consideration of the visibility of the drawing. In addition, In FIG. 1A, configurations not necessarily present on the same cross section are shown.

In addition, in the present specification, a side on which the semiconductor device 1a is mounted when viewed from a mounting substrate 2a is referred to as an upper side, a side of the mounting substrate 2a is referred to as a lower side, and a vertical direction is referred to as a Z direction. Both the X direction and the Y direction are directions along an orientation of the surface of the mounting substrate 2a, and the X direction and the Y direction are directions orthogonal to each other. In addition, a direction indicated by an arrow of each axis is referred to as a positive direction, and a direction opposite to the arrow of each axis is referred to as a negative Z direction.

For example, the semiconductor system SA according to Embodiment 1 is a solid state drive (SSD) or the like. As shown in FIG. 1A, the semiconductor system SA is provided with a semiconductor device 1a, a semiconductor device 1b, and a mounting substrate 2a.

The semiconductor device 1b includes a wiring substrate 30b and a controller chip 10b sealed on the wiring substrate 30b. The semiconductor device 1a includes semiconductor chips CP1 to CP8 and CP11 to CP18 configured as a non-volatile memory or the like as will be described later, and the controller chip 10b is configured as a memory controller incorporating an integrated circuit capable of controlling an operation of the semiconductor device 1a. A plurality of electrode terminals 40b are provided on a lower surface of the wiring substrate 30b. Each of the plurality of electrode terminals 40b functions as an external connection terminal of the semiconductor device 1b by being connected to the mounting substrate 2a.

The mounting substrate 2a is a printed wiring substrate (printed circuit board: PCB) or the like in which insulating layers and conductive layers are alternately stacked a plurality of times. For example, each of a plurality of conductive layers including the conductive layer 21 shown in FIG. 1A is formed with a metal such as Cu. One end of each of the plurality of conductive layers is connected to the plurality of electrode terminals 40b of the semiconductor device 1b, and the other end is connected to a corresponding electrode terminal among the plurality of electrode terminals provided in a ball grid array 40a of the semiconductor device 1a to be described later. Each of the plurality of conductive layers functions as a signal line that sends and receives various signals between the semiconductor device 1b and the semiconductor device 1a.

Among the plurality of conductive layers, the conductive layer 21 is a signal line that sends and receives a first signal between the semiconductor device 1b and the semiconductor device 1a. For example, the first signal is a command signal, and is one of a command latch enable signal (CLE signal), an address latch enable signal (ALE signal), a write enable signal (WE signal), and the like. For example, the length of the conductive layer 21 is approximately 200 mm. The first signal is sent and received between the semiconductor device 1b and the semiconductor device 1a through the conductive layer 21 at, for example, approximately 1.4 ns.

The semiconductor device 1a is configured as a semiconductor package in which the first semiconductor module 10a and the second semiconductor module 11a are sealed on the wiring substrate 30a.

The wiring substrate 30a is provided with a core layer 32a, solder resist layers 31a and 33a, and a plurality of conductive layers including a conductive layer 35a.

The core layer 32a is disposed at a center portion of the wiring substrate 30a, and is a prepreg configured with a carbon fiber, a glass fiber, an aramid fiber, or the like impregnated with a thermosetting resin such as an epoxy resin before curing.

The plurality of conductive layers have wiring patterns extending in the core layer 32a in the XY direction, and vias connecting these wiring patterns to each other in the Z direction. For example, the plurality of conductive layers are formed with Cu or the like.

The plurality of conductive layers extend in the core layer 32a in the Z direction, are connected to any of the first semiconductor module 10a and the second semiconductor module 11a on the upper surface of the core layer 32a, and are connected to any of the electrode terminals of the ball grid array 40a on the lower surface of the core layer 32a. The plurality of conductive layers function as signal lines for transmitting the plurality of signals transmitted from the plurality of conductive layers of the above-described mounting substrate 2a to the first and second semiconductor modules 10a and 11a between the first semiconductor module 10a, the second semiconductor module 11a, and the ball grid array 40a.

For example, among the plurality of conductive layers, the conductive layer 35a is a signal line that transmits, for example, the first signal transmitted from the conductive layer 21 of the mounting substrate 2a described above to the first and second semiconductor modules 10a and 11a, and includes a first conductive layer 36a, a second conductive layer 37a, and the like.

The first conductive layer 36a is connected to the first semiconductor module 10a on the upper surface of the core layer 32a and is connected to the ball grid array 40a on the lower surface of the core layer 32a. That is, the first conductive layer 36a is a signal line that sends and receives the first signal between the first semiconductor module 10a and the ball grid array 40a. Hereinafter, the first conductive layer 36a may be referred to as a first signal line 36a.

The second conductive layer 37a is connected to the second semiconductor module 11a on the upper surface of the core layer 32a and is connected to the ball grid array 40a on the lower surface of the core layer 32a. That is, the second conductive layer 37a is a signal line that sends and receives the first signal between the second semiconductor module 11a and the ball grid array 40a. Hereinafter, the second conductive layer 37a may be referred to as a second signal line 37a.

In addition, a crosslinking wiring 100a for electrically connecting the first signal line 36a and the second signal line 37a to each other is provided between the first signal line 36a and the second signal line 37a. The crosslinking wiring 100a is a configuration that is added to the semiconductor device 1a completed through a predetermined manufacturing step before being mounted on the mounting substrate 2a, as necessary, as will be described later. Details of the crosslinking wiring 100a will be described later.

For example, the solder resist layers 31a and 33a are formed with an insulating resin. The solder resist layer 31a covers the upper surface of the core layer 32a, and the solder resist layer 33a covers the lower surface of the core layer 32a. The solder resist layer 33a has an opening 330a on the lower surface of the core layer 32b between an electrode terminal to which the first signal line 36a is connected and an electrode terminal to which the second signal line 37a is connected among the plurality of electrode terminals of the ball grid array 40a. The crosslinking wiring 100a is exposed to the opening 330a. The solder resist layer 33a is an example of an insulating layer.

Hereinafter, the upper surface of the wiring substrate 30a, that is, the surface on the side on which the solder resist layer 31a is provided may be referred to as a surface 310a as a first surface, and the lower surface of the wiring substrate 30a, that is, the surface on the side on which the solder resist layer 33a is provided may be referred to as a surface 320a as a second surface. The surface 320a is also an example of a third surface.

The first semiconductor module 10a and the second semiconductor module 11a are mounted on the surface 310a of the wiring substrate 30a. Each of the first semiconductor module 10a and the second semiconductor module 11a has a configuration in which one or more semiconductor chips are stacked. The semiconductor chip is a piece such as a Si substrate on which a semiconductor element is mounted. For example, the semiconductor element mounted on the semiconductor chip is a non-volatile memory such as a NAND flash memory.

More specifically, the first semiconductor module 10a has, for example, the semiconductor chips CP1 to CP8, and the second semiconductor module 11a has, for example, the semiconductor chips CP11 to CP18. Each of spacers 70 is provided between the semiconductor chips CP4 and CP5 and between the semiconductor chips CP14 and CP15. The spacer 70 is a piece such as a Si substrate.

Each of the semiconductor chips CP1 to CP8 and CP11 to CP18 is stacked so as to be shifted to each other in a predetermined direction along the surface 310a of the wiring substrate 30a. As a result, a portion on the upper surface of each of the semiconductor chips CP1 to CP7 and CP11 to CP17 does not overlap with the semiconductor chips CP2 to CP8 and CP12 to CP18 directly above. Each of the portions and the upper surfaces of the semiconductor chips CP8 and CP18 is provided with an electrode (not shown). For example, the electrodes are connected to each of the first signal line 36a and the second signal line 37a on the surface 310a of the wiring substrate 30a by the bonding wire 60.

The ball grid array 40a described above is provided on the surface 320a of the wiring substrate 30a. The ball grid array 40a includes the plurality of electrode terminals. The ball grid array 40a functions as an external connection terminal of the semiconductor device 1a by being connected to an electrode pad (not shown) of the mounting substrate 2a.

More specifically, as shown in FIG. 1B, the ball grid array 40a includes a plurality of electrode terminals 41a provided in a region R10 overlapping the mounting position of the first semiconductor module 10a mounted on the surface 310a of the wiring substrate 30a in the Z direction, and a plurality of electrode terminals 42a provided in a region R11 overlapping the mounting position of the second semiconductor module 11a mounted on the surface 310a of the wiring substrate 30a in the Z direction.

The plurality of electrode terminals 41a provided in the region R10 are electrically connected to the first semiconductor module 10a through the plurality of conductive layers 35a. For example, a first electrode 411 of the plurality of electrode terminals 41a is connected to the first signal line 36a and is electrically connected to the first semiconductor module 10a through the first signal line 36a.

The plurality of electrode terminals 42a provided in the region R11 electrically are connected to the second semiconductor module 11a through the plurality of conductive layers 35a. For example, a second electrode 421 of the plurality of electrode terminals 42a is connected to the second signal line 37a and is electrically connected to the second semiconductor module 11a through the second signal line 37a.

In addition, as shown in FIG. 1A, the surface of the first electrode 411 on the side of the mounting substrate 2a is connected to the conductive layer 21 of the mounting substrate 2a. As a result, the first signal is communicated between (e.g., input to and/or output from) the first semiconductor module 10a and the semiconductor device 1b through the conductive layer 21, the first electrode 411, and the first signal line 36a.

In addition, as described above, the first signal line 36a and the second signal line 37a are electrically connected to each other through the crosslinking wiring 100a. As a result, the first signal is input to and/or output from the second semiconductor module 11a through the first signal line 36a and the second signal line 37a.

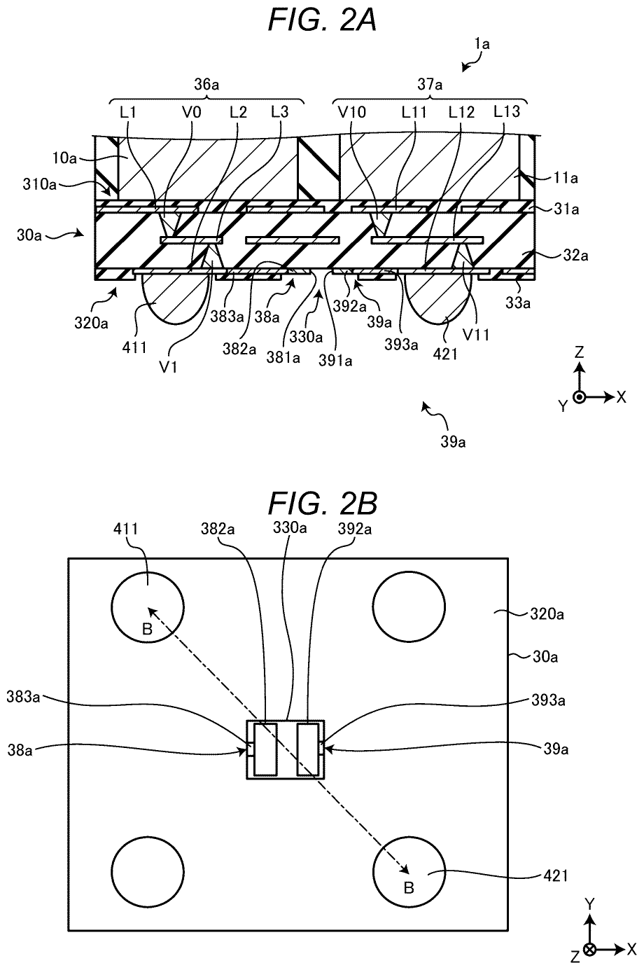

FIGS. 2A and 2B are views showing a detailed configuration of the semiconductor device 1a according to Embodiment 1. FIG. 2A is an enlarged cross-sectional view of the semiconductor device 1a taken along the line A-A of FIG. 1B, and FIG. 2B is an enlarged plan view of the semiconductor device 1a when viewed from the negative Z direction.

Meanwhile, FIGS. 2A and 2B are views showing the state of the semiconductor device 1a before being mounted on the mounting substrate 2a. Therefore, a part of the configuration of the crosslinking wiring 100a and the like is not formed in the semiconductor device 1a of FIGS. 2A and 2B. In addition, in FIGS. 2A and 2B, the configuration of the wiring substrate 30a of the semiconductor device 1a will be mainly described. Therefore, the description of a part of configurations such as the configurations of the first semiconductor module 10a and a second semiconductor module 11a may be omitted.

As described above, the wiring substrate 30a is provided with the core layer 32a, the first signal line 36a and the second signal line 37a extending in the core layer 32a, and the solder resist layers 31a and 33a.

The first signal line 36a has a wiring layer L1 that extends along the surface 310a and is connected to the first semiconductor module 10a through the above-described bonding wire 60 (refer to FIG. 1A), and a wiring layer L2 that extends along the surface 320a and is connected to the first electrode 411 and the third signal line 38a. In addition, a wiring layer L3 and via layers V0 and V1, and the like that connect the wiring layers L1 and L2 to each other are provided in the core layer 32a. For example, the wiring layer L3 extends between the wiring layer L1 and the wiring layer L2 in the XY direction. The via layer V0 extends in the core layer 32a between the wiring layers L1 and L3 in the Z direction to connect these wiring layers L1 and L3, and the via layer V1 extends in the core layer 32a between the wiring layers L3 and L2 in the Z direction to connect these wiring layers L3 and L2. Meanwhile, the number and disposition of the wiring layer L3 and the via layers V0 and V1 that connect the wiring layers L1 and L2 are predetermined.

The third signal line 38a is formed with a conductive member such as Cu. The third signal line 38a includes a wiring portion 383a connected to the wiring layer L2 and an end portion 381a connected to the wiring portion 383a. The wiring portion 383a and the end portion 381a are connected to the wiring layer L2 and extend in the positive X direction along the surface 320a. The end portion 381a is exposed from the opening 330a of the solder resist layer 33a. That is, the end portion 381a of the third signal line 38a reaches the surface 320a. Alternatively, the end portion 381a of the third signal line 38a is also drawn out to the surface 320a.

The second signal line 37a has a wiring layer L11 that extends along the surface 310a and is connected to the second semiconductor module 11a through the above-described bonding wire 60 (refer to FIG. 1A), and a wiring layer L12 that extends along the surface 320a and is connected to the second electrode 421 and the fourth signal line 39a. In addition, a wiring layer L13 and via layers V10 and V11, and the like that connect the wiring layers L11 and L12 to each other are provided in the core layer 32a. For example, the wiring layer L13 extends between the wiring layer L11 and the wiring layer L12 in the XY direction. The via layer V10 extends in the core layer 32a between the wiring layers L11 and L13 in the Z direction to connect these wiring layers L11 and L13, and the via layer V11 extends in the core layer 32a between the wiring layers L13 and L12 in the Z direction to connect these wiring layers L13 and L12. Meanwhile, the number and disposition of the wiring layer L13 and the via layers V10 and V11 that connect the wiring layers L11 and L12 are predetermined.

The fourth signal line 39a is formed with a conductive member such as Cu. The fourth signal line 39a includes a wiring portion 393a connected to the wiring layer L12 and an end portion 391a connected to the wiring portion 393a. The wiring portion 393a and the end portion 391a are connected to the wiring layer L12 and extend along the surface 320a in the negative X direction. The end portion 391a is exposed from the opening 330a of the solder resist layer 33a. That is, the end portion 391a of the fourth signal line 39a reaches the surface 320a. Alternatively, the end portion 391a of the fourth signal line 39a is also drawn out to the surface 320a.

With such a configuration, the first signal line 36a and the second signal line 37a can be electrically connected to each other by forming the crosslinking wiring 100a that connects the end portion 381a and the end portion 391a later as necessary. That is, each of the end portion 381a and the end portion 391a is configured as crosslinking terminals 382a and 392a when the crosslinking wiring 100a is formed later.

As shown in FIG. 2A, each of the crosslinking terminals 382a and 392a is provided on the lower surface of the core layer 32a. That is, each of the crosslinking terminals 382a and 392a is provided at the same height position as that of each of the wiring layer L2 and the wiring layer L12 extending along the lower surface of the core layer 32a. In addition, each of the crosslinking terminals 382a and 392a is not covered with the solder resist layer 33a, and thus each is exposed to the surface 320a. The surface 320a is a surface facing the mounting substrate 2a when the semiconductor device 1a is mounted on the mounting substrate 2a (refer to FIGS. 1A and 1B). That is, each of the crosslinking terminals 382a and 392a is exposed to the surface 320a of the semiconductor device 1a facing the mounting substrate 2a. Since each of the crosslinking terminals 382a and 392a is exposed to the surface 320a of the semiconductor device 1a, it is easy to form the crosslinking wiring 100a that cross-links between the crosslinking terminals 382a and 392a. In addition, after the semiconductor device 1a is manufactured and before the semiconductor device 1a is mounted on the mounting substrate 2a, it is possible to form the crosslinking wiring 100a that cross-links between the crosslinking terminals 382a and 392a, as will be described later.

As shown in FIG. 2B, it is preferable that each of the crosslinking terminals 382a and 392a is formed in a rectangular shape in which the length of one side along the Y direction is longer than the width along the Y direction of the wiring portion 383a and the wiring portion 393a extending in the X direction when viewed in the Z direction. In addition, the crosslinking terminals 382a and 392a are arranged side by side in a predetermined direction with an interval of 1 mm or less, for example. As a result, it is easy to form the crosslinking wiring 100a that cross-links between the crosslinking terminals 382a and 392a.

In addition, the crosslinking terminals 382a and 392a reach a position on the surface 320a on the line connecting the first electrode 411 and the second electrode 421 with the shortest distance. Specifically, as shown in FIG. 2B, the crosslinking terminals 382a and 392a are disposed at positions facing each other across the line B-B connecting the first electrode 411 and the second electrode 421 in a straight line. As described above, the third signal line 38a extends from the wiring layer L2 connected to the first electrode 411, and the fourth signal line 39a extends from the wiring layer L12 connected to the second electrode 412. Therefore, by arranging the crosslinking terminals 382a and 392a to face each other on the line B-B, the lengths of the third signal line 38a and the fourth signal line 39a can be further shortened.

At this time, in the example of FIG. 2B, the crosslinking terminals 382a and 392a are faced each other in the direction along the X direction, and the crosslinking terminals 382a and 392a may be faced each other in the direction along the Y direction, or may be faced each other on a line connecting the first electrode 411 and the second electrode 421.

### Method of Manufacturing Semiconductor System

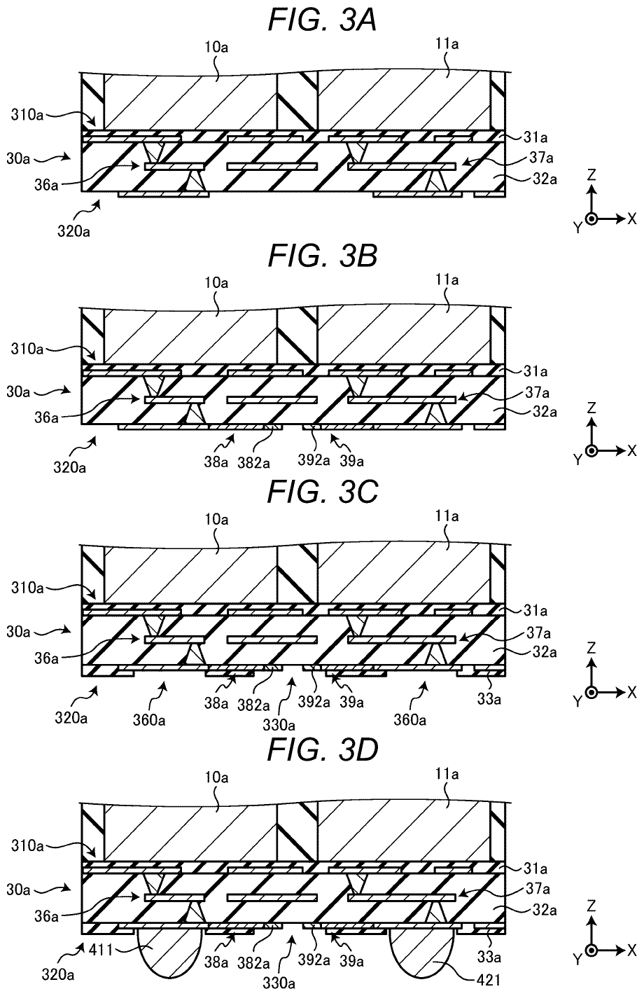

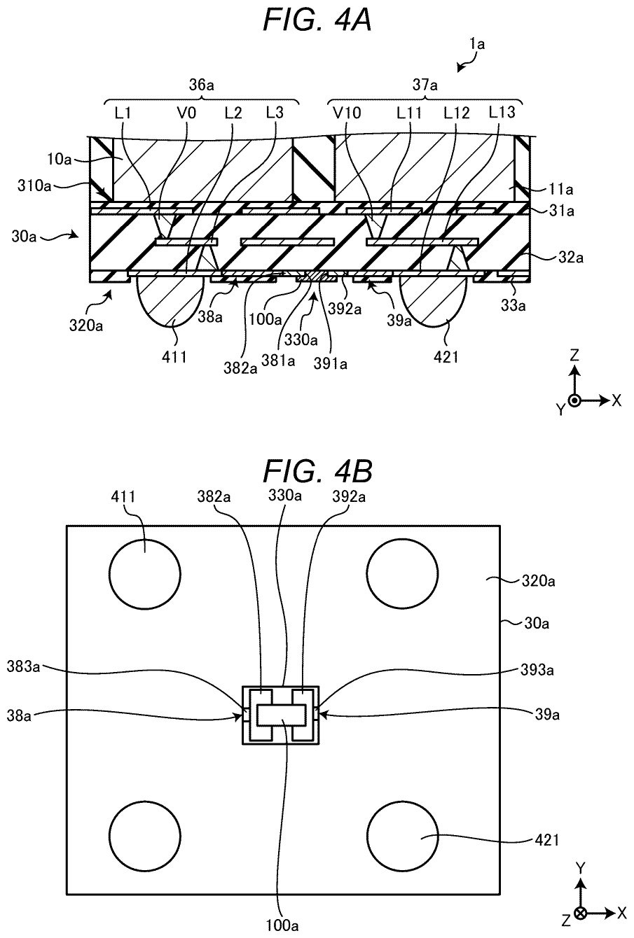

Next, a method of manufacturing a semiconductor system SA including a method of manufacturing the semiconductor device 1a according to Embodiment 1 will be described with reference to FIGS. 3 and 4.

First, the method of manufacturing the semiconductor device 1a will be described with reference to FIGS. 3A to 3D. The manufacturing step of the semiconductor device 1a shown in FIGS. 3A to 3D is performed as a part of the manufacturing step of the semiconductor system SA.

FIGS. 3A to 3D are views sequentially showing a part of a procedure of the method of manufacturing the semiconductor device 1a according to Embodiment 1. Meanwhile, in FIGS. 3A to 3D, among the manufacturing steps of the semiconductor device 1a, the steps related to the formation of the wiring substrate 30a will be mainly described. Therefore, the description of a part of steps of the manufacturing steps of the first semiconductor module 10a and the second semiconductor module 11a may be omitted.

As shown in FIG. 3A, the first signal line 36a and the second signal line 37a are formed on the wiring substrate 30a.

As shown in FIG. 3B, a third signal line 38a connected to the first signal line 36a and extending along the surface 320a and a fourth signal line 39a connected to the second signal line 37a and extending along the surface 320a are formed. The crosslinking terminals 382a and 392a are formed when the third signal line 38a and the fourth signal line 39a are formed. Meanwhile, the third signal line 38a and the crosslinking terminal 382a may be collectively formed, and the fourth signal line 39a and the crosslinking terminal 392a may be collectively formed. Furthermore, all of the third signal line 38a, the fourth signal line 39a, and the crosslinking terminals 382a and 392a may be collectively formed.

As shown in FIG. 3C, the surface 320a is covered with the solder resist layer 33a. At this time, the opening 330a for exposing the crosslinking terminals 382a and 392a and an opening 360a for forming the ball grid array 40a are formed in the solder resist layer 33a.

As shown in FIG. 3D, the ball grid array 40a including the first electrode 411 and the second electrode 421 is formed in the opening 360a. Consequently, the manufacturing of the semiconductor device 1a according to Embodiment 1 is completed.

The semiconductor device 1a manufactured in this manner is mounted on the mounting substrate 2a, and is shipped as a product after being completed as the semiconductor system SA. The semiconductor system SA may be required to have various specifications depending on the application as a product.

For example, as a first specification, a specification may be requested in which the same signal from the semiconductor device 1b is individually input and output to each of the first semiconductor module 10a and the second semiconductor module 11a through different signal lines. On the other hand, for example, as a second specification, a specification may be requested in which the same signal from the semiconductor device 1b is input and output to the first semiconductor module 10a and the second semiconductor module 11a through a common signal line.

For example, when the number of modules such as a first semiconductor module 10a and a second semiconductor module 11a provided in the semiconductor device 1a is small, the second specification is often adopted. On the other hand, when the number of modules provided in the semiconductor device 1a is large, the first specification is often adopted. That is, for example, the first specification may be applied when it is desired to increase the capacity as the SSD of the semiconductor system SA. This is because the signal transmission speed can be prevented from decreasing as the number of modules to be one unit for input and output targets of the signal increases by dividing the signal line for transmitting the same signal for each module.

In the present embodiment, as described above, the semiconductor device 1a is manufactured so that the crosslinking wiring 100a described later can be added later. As a result, the semiconductor device 1a for the first specification can be diverted to the semiconductor device 1a for the second specification.

When the above-described second specification is required, in the manufacturing step of the semiconductor system SA, a process of forming the crosslinking wiring 100a that connects the crosslinking terminals 382a and 392a of the semiconductor device 1a is performed. The process of forming the crosslinking wiring 100a is performed after it is determined that the semiconductor device 1a is adapted to the second specification, that is, for example, before the semiconductor device 1a stocked as a finished product is mounted on the mounting substrate 2a. The following process may not be performed when the second specification is not requested.

FIGS. 4A and 4B are views showing a detailed configuration of the semiconductor device according to Embodiment 1, and are views showing the state after being diverted from a first specification to a second specification. FIG. 4A is an enlarged cross-sectional view of the semiconductor device 1a corresponding to FIG. 2A, and FIG. 4B is an enlarged plan view of the semiconductor device 1a corresponding to FIG. 2B.

As shown in FIGS. 4A and 4B, the crosslinking wiring 100a is formed, which connects to cross the surfaces of the crosslinking terminals 382a and 392a of the semiconductor device 1a. For example, the crosslinking wiring 100a is formed by an ink jet method. The crosslinking wiring 100a is formed by including a conductive member such as Cu ejected from an ink jet head. For example, the conductive member may be Ag or Au. The crosslinking wiring 100a is formed, so that the crosslinking terminals 382a and 392a are electrically connected to each other. As a result, the first signal line 36a and the second signal line 37a are electrically connected to each other through the third signal line 38a and the fourth signal line 39a.

Next, although not shown, the semiconductor device 1a on which the crosslinking wiring 100a is formed is mounted on the mounting substrate 2a. As a result, the first signal input and output from the semiconductor device 1b is input and output to and from the first semiconductor module 10a and the second semiconductor module 11a through each of the conductive layer 21, the first electrode 411, the first signal line 36a, and the second signal line 37a. Consequently, the manufacturing of the semiconductor system SA according to Embodiment 1 is completed above.

### COMPARATIVE EXAMPLE

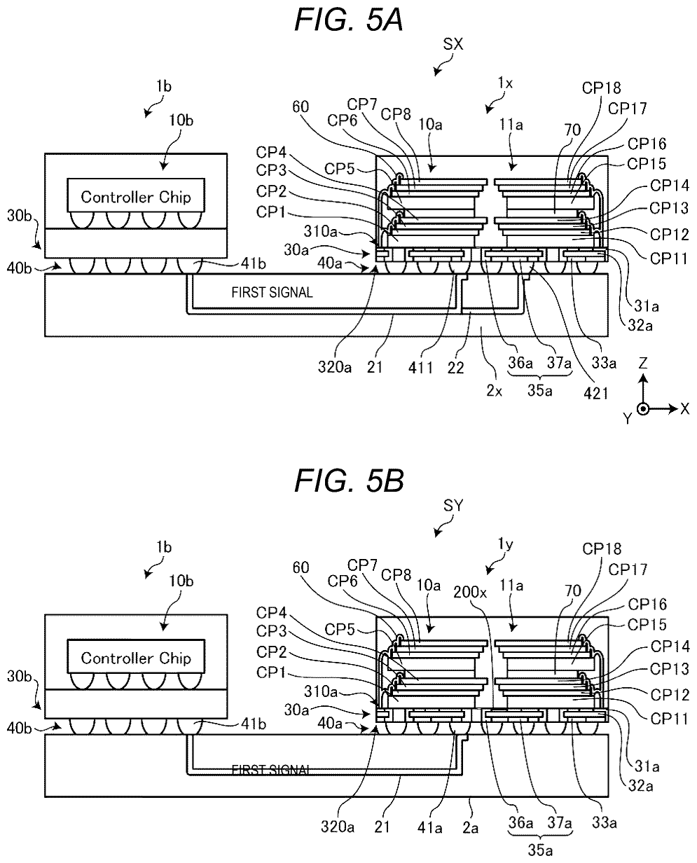

FIGS. 5A and 5B are views showing a semiconductor system according to a comparative example. Each of FIGS. 5A and 5B show the configuration examples of semiconductor systems SX and SY of the comparative example.

As described above, various specifications are required for the semiconductor system according to the application as a product.

For example, as a first method of obtaining the semiconductor system having the second specification described above, a method is used in which the semiconductor device 1x is manufactured for the first specification, and the semiconductor system is applied to the second specification by changing a wiring layout of the mounting substrate 2a. Specifically, as shown in FIG. 5A, the conductive layer 21 that connects the semiconductor device 1b and the first electrode 411, and the conductive layer 22 having one end portion connected to the conductive layer 21 and the other end portion connected to the second electrode 421 are provided in the mounting substrate 2a to obtain a mounting substrate 2x. As a result, it is possible to obtain the semiconductor system SX capable of inputting and outputting the first signal from the semiconductor device 1b to the first semiconductor module 10a and the second semiconductor module 11a through each of the conductive layers 21 and 22.

In addition, as a second method of obtaining the semiconductor system having the second specification, a method of applying the semiconductor system to the second specification by changing the wiring layout in the semiconductor device 1x may be used. Specifically, as shown in FIG. 5B, a conductive layer 200x that connects the first signal line 36a and the second signal line 37a is formed on the surface 310a in advance. As a result, it is possible to obtain the semiconductor device 1y and the semiconductor system SY in which the first signal can be input and output from the semiconductor device 1b to the first semiconductor module 10a and the second semiconductor module 11a through the first signal line 36a and the conductive layer 200x without changing the wiring layout of the mounting substrate 2a.

However, in order to be able to correspond to both of the first and second specifications, in a first method, it is necessary to prepare both the mounting substrate 2x corresponding to the first specification and the mounting substrate 2a corresponding to the second specification. On the other hand, in a second method, it is necessary to prepare both the semiconductor device 1x corresponding to the first specification and the semiconductor device 1y corresponding to the second specification.

Furthermore, in the first method, the conductive layer 22 branching from the conductive layer 21 is newly provided, so that the wiring length is increased. As a result, the amount of power loss may increase, and as a result, the electrical characteristics of the semiconductor system SX may deteriorate.

### Overview

The wiring substrate 30a of the semiconductor device 1a according to Embodiment 1 includes the first signal line 36a, the second signal line 37a, the third signal line 38a connected to the first signal line 36a and having the end portion 381a reaching the surface 320a, and the fourth signal line 39a connected to the second signal line 37a and having the end portion 391a reaching the surface 320a. The first signal line 36a and the second signal line 37a input and output the first signal to and from the first semiconductor module 10a and the second semiconductor module 11a.

As a result, for example, before mounting the semiconductor device 1a on the mounting substrate 2a, the end portion 381a and the end portion 391a that reaches the surface 320a can be connected to each other, and the first signal line 36a and the second signal line 37a can be electrically connected to each other, as necessary. Since the connection of the signal lines can be flexibly changed according to the application required for the semiconductor system SA, it is not necessary to prepare, for example, a plurality of semiconductor devices 1x and 1y having different specifications in advance. That is, the generality of the semiconductor device 1a with respect to the design of the semiconductor system SA is increased.

In addition, since the first signal line 36a and the second signal line 37a can be connected without changing the wiring layout of mounting the substrate 2a, the electrical characteristics of the semiconductor system SA can be prevented from being reduced due to the extension of the wiring length of the mounting substrate 2a.

In addition, in the semiconductor device 1a according to Embodiment 1, the end portion 381a and the end portion 391a reach the position of the surface 320a that is on a line connecting the first electrode 411 and the second electrode 421 with the shortest distance.

As a result, since the lengths of the third signal line 38a and the fourth signal line 39a can be further shortened, the amount of power loss is reduced, and the deterioration of the electrical characteristics of the semiconductor system SA can be prevented.

### Modification Example 1

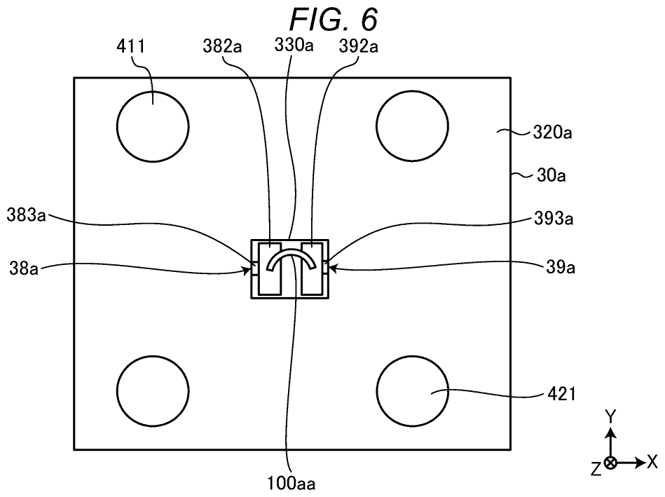

FIG. 6 is a view showing Modification Example 1 according to Embodiment 1.

In Modification Example 1 according to Embodiment 1, a configuration of a crosslinking wiring is different from that of Embodiment 1. In the following, the same reference numeral is attached to the same configuration as that in the above-described embodiment, and the description thereof may be omitted.

As shown in FIG. 6, a crosslinking wiring according to Modification Example 1 is formed by including a bonding wire 100aa. Specifically, one end portion of the bonding wire 100aa formed with a conductive member such as Cu is bonded to the crosslinking terminal 382a, and the other end portion is bonded to the crosslinking terminal 392a. As a result, the crosslinking terminals 382a and 392a are connected to each other through the bonding wire 100aa, and the first signal line 36a and the second signal line 37a are electrically connected to each other.

### Modification Example 2

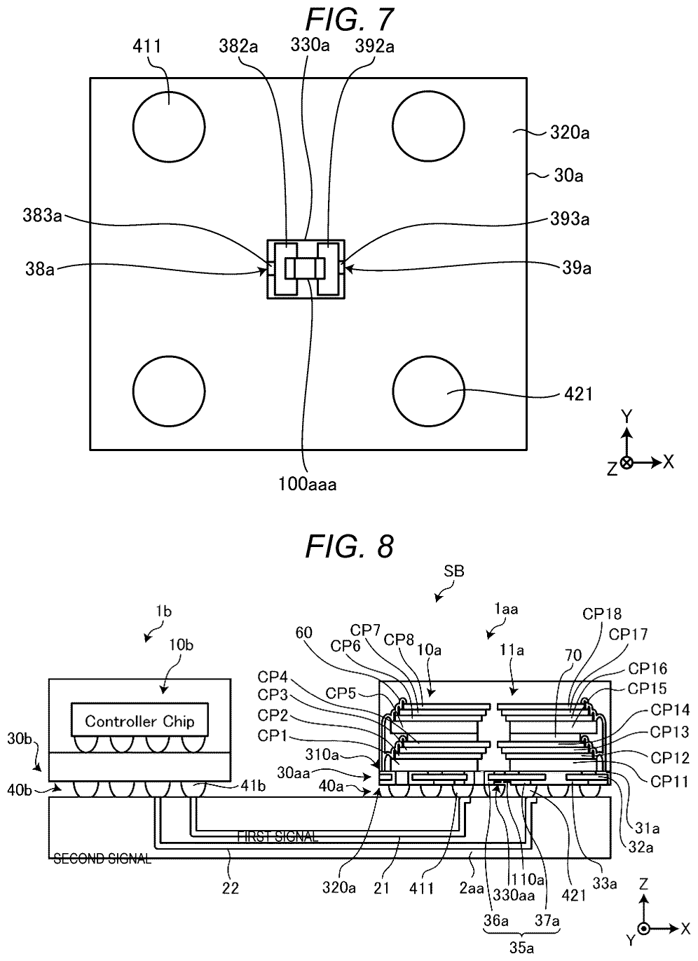

FIG. 7 is a view showing Modification Example 2 according to Embodiment 1.

In Modification Example 2 according to Embodiment 1, a configuration of a crosslinking wiring is different from those of Embodiment 1 and Modification Example 1. In the following, the same reference numeral is attached to the same configuration as that in the above-described embodiment, and the description thereof may be omitted.

As shown in FIG. 7, a crosslinking wiring according to Modification Example 2 is formed by including a low resistance component 100aaa. Specifically, one end portion of the low resistance component 100aaa is connected to the crosslinking terminal 382a, and the other end portion is connected to the crosslinking terminal 392a. As a result, the crosslinking terminals 382a and 392a are connected to each other through the low resistance component 100aaa, and the first signal line 36a and the second signal line 37a are electrically connected to each other. The low resistance component 100aaa has a resistance value of approximately 0Ω, and thus the power loss in the crosslinking wiring can be further reduced. For example, the low resistance component 100aaa may be a passive component.

### Embodiment 2

Hereinafter, Embodiment 2 will be described with reference to FIGS. 8 to 11.

In Embodiment 2, the semiconductor device for the second specification can be diverted to the semiconductor device for the first specification. As described above, the first specification is a specification in which different signals are individually input and output from the semiconductor device 1b to each of the first semiconductor module 10a and the second semiconductor module 11a.

While the semiconductor device 1a of above-described Embodiment 1 is a semiconductor device for the first specification that can be diverted to the second specification, the semiconductor device according to Embodiment 2 is a semiconductor device for the second specification that can be diverted to the first specification. When the semiconductor device for the second specification needs to be diverted to the first specification, the crosslinking wiring that connects the cross-linking end portions of the semiconductor device may be cut. In the following, the same reference numeral is attached to the same configuration as that in the above-described embodiment, and the description thereof may be omitted.

### Configuration Example of Semiconductor Device

FIG. 8 is a schematic diagram showing an example of a configuration of a semiconductor system SB according to Embodiment 2. More specifically, FIG. 8 is a cross-sectional view taken along the XZ direction of the semiconductor system SB.

Meanwhile, in FIG. 8, hatching is omitted in consideration of the visibility of the drawing. In addition, FIG. 8 shows configurations that are not necessarily present in the same cross section, and a part of the wiring or the like is omitted.

As shown in FIG. 8, the semiconductor system SB according to Embodiment 2 is provided with a mounting substrate 2aa, a semiconductor device 1b, and a semiconductor device 1aa. The conductive layers 21 and 22 are formed on the mounting substrate 2aa. The conductive layer 21 is a signal line that sends and receives the first signal between the semiconductor device 1b and the semiconductor device 1aa. The conductive layer 22 is a signal line that sends and receives the second signal between the semiconductor device 1b and the semiconductor device 1aa. The second signal is the same command signal as the first signal, and is one of a command latch enable signal (CLE signal), an address latch enable signal (ALE signal), a write enable signal (WE signal), and the like, for example.

A wiring substrate 30aa is provided with a core layer 32a, solder resist layers 31a and 33a, a first conductive layer 36a, and a second conductive layer 37a.

The first conductive layer 36a is connected to the first semiconductor module 10a on the surface 310a of the wiring substrate 30a and is connected to the first electrode 411 on the surface 320a of the wiring substrate 30a. In addition, the second conductive layer 37a is connected to the second semiconductor module 11a on the surface 310a of the wiring substrate 30a and is connected to the second electrode 421 on the surface 320a of the wiring substrate 30a. In addition, as will be described later, the crosslinking wiring 110a provided between the first signal line 36a and the second signal line 37a so as to connect these lines is cut in the vicinity of the center thereof. As a result, in the semiconductor device 1aa according to Embodiment 2, the first signal line 36a and the second signal line 37a are electrically separated from each other. A cutting portion of the crosslinking wiring 110a is exposed to an opening 330aa of the solder resist layer 33a. Details of the crosslinking wiring 110a will be described later.

The surface of the first electrode 411 on the side of the mounting substrate 2aa is connected to the conductive layer 21 of the mounting substrate 2aa, and the surface of the second electrode 421 on the side of the mounting substrate 2aa is connected to the conductive layer 22 of the mounting substrate 2aa. In addition, as described above, the first signal line 36a and the second signal line 37a are electrically separated from each other. Therefore, the first signal input and output from the semiconductor device 1b is input and output to and from the first semiconductor module 10a through the conductive layer 21, and the second signal input and output from the semiconductor device 1b is input and output to and from the second semiconductor module 11a through the conductive layer 22.

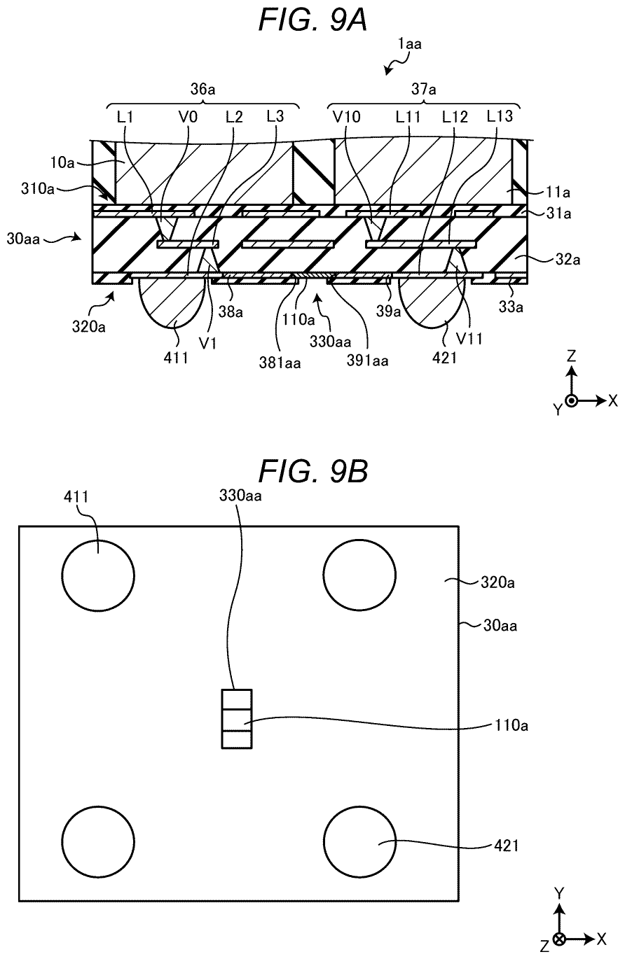

FIGS. 9A and 9B are views showing a detailed configuration of the semiconductor device 1aa according to Embodiment 2. FIG. 9A is an enlarged cross-sectional view of the semiconductor device 1aa corresponding to FIG. 2A, and FIG. 9B is an enlarged plan view of the semiconductor device 1aa corresponding to FIG. 2B.

Meanwhile, FIGS. 9A and 9B are views showing the state of the semiconductor device 1aa before being mounted on the mounting substrate 2aa. Therefore, the state before the crosslinking wiring 110a is cut is shown in the semiconductor device 1aa of FIGS. 9A and 9B. In addition, in FIGS. 9A and 9B, the configuration of the wiring substrate 30aa of the semiconductor device 1aa will be mainly described. Therefore, the description of a part of configurations such as the configurations of the first semiconductor module 10a and a second semiconductor module 11a may be omitted.

As described above, the wiring substrate 30aa is provided with the core layer 32a, the first signal line 36a and the second signal line 37a extending in the core layer 32a, and the solder resist layers 31a and 33a.

The first signal line 36a has a wiring layer L1 that extends along the surface 310a and is connected to the first semiconductor module 10a through the above-described bonding wire 60 (refer to FIG. 1A), and a wiring layer L2 that extends along the surface 320a and is connected to the first electrode 411 and the third signal line 38a. In addition, a wiring layer L3 and via layers V0 and V1, and the like that connect the wiring layers L1 and L2 to each other are provided in the core layer 32a. For example, the wiring layer L3 extends between the wiring layer L1 and the wiring layer L2 in the XY direction. The via layer V0 extends in the core layer 32a between the wiring layers L1 and L3 in the Z direction to connect these wiring layers L1 and L3, and the via layer V1 extends in the core layer 32a between the wiring layers L3 and L2 in the Z direction to connect these wiring layers L3 and L2.

The third signal line 38a is formed with a conductive member such as Cu. The third signal line 38a is connected to the wiring layer L2 and extends in the positive X direction along the surface 320a. As a result, the end portion 381aa of the third signal line 38a is exposed from the opening 330aa of the solder resist layer 33a. That is, the end portion 381aa of the third signal line 38a reaches the surface 320a.

The second signal line 37a has a wiring layer L11 that extends along the surface 310a and is connected to the second semiconductor module 11a through the above-described bonding wire 60 (refer to FIG. 1A), and a wiring layer L12 that extends along the surface 320a and is connected to the second electrode 421 and the fourth signal line 39a. In addition, a wiring layer L13 and via layers V10 and V11, and the like that connect the wiring layers L11 and L12 to each other are provided in the core layer 32a. For example, the wiring layer L13 extends between the wiring layer L11 and the wiring layer L12 in the XY direction. The via layer V10 extends in the core layer 32a between the wiring layers L11 and L13 in the Z direction to connect these wiring layers L11 and L13, and the via layer V11 extends in the core layer 32a between the wiring layers L13 and L12 in the Z direction to connect these wiring layers L13 and L12.

The fourth signal line 39a is formed with a conductive member such as Cu. The fourth signal line 39a is connected to the wiring layer L12 and extends along the surface 320a in the negative X direction. As a result, the end portion 391aa of the fourth signal line 39a is exposed from the opening 330aa of the solder resist layer 33a. That is, the end portion 391aa of the fourth signal line 39a reaches the surface 320a.

The surface 320a is covered with the solder resist layer 33a except for the region in which the opening 330aa, the first electrode 411, and the second electrode 421 are formed. The crosslinking wiring 110a is exposed to the opening 330aa. In order to divert the semiconductor device 1aa configured for the second specification to the first specification, the crosslinking wiring 110a exposed to the opening 330aa may be cut later. As a result, the first signal line 36a and the second signal line 37a are electrically separated from each other.

### Method of Manufacturing Semiconductor Device

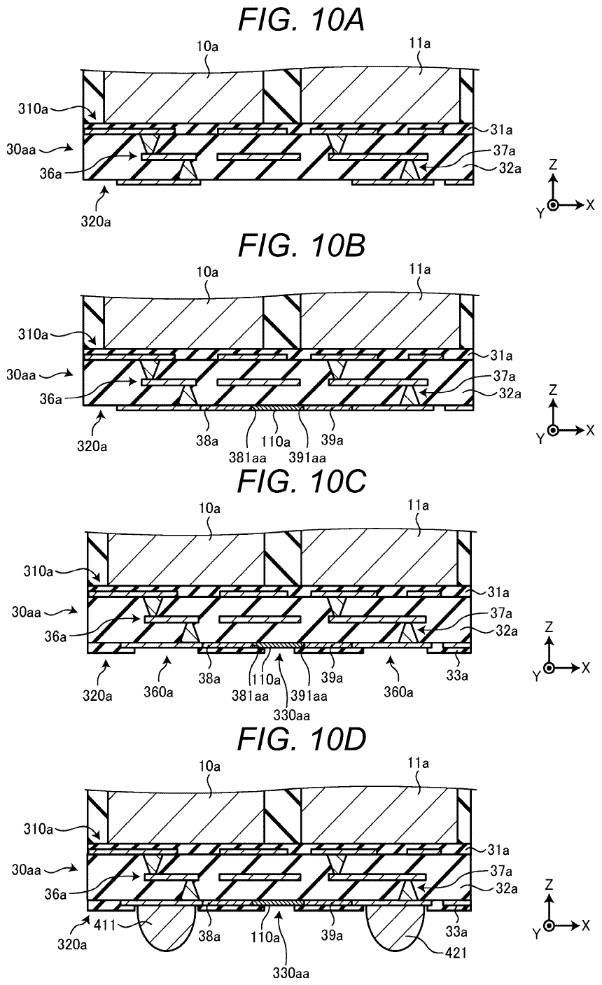

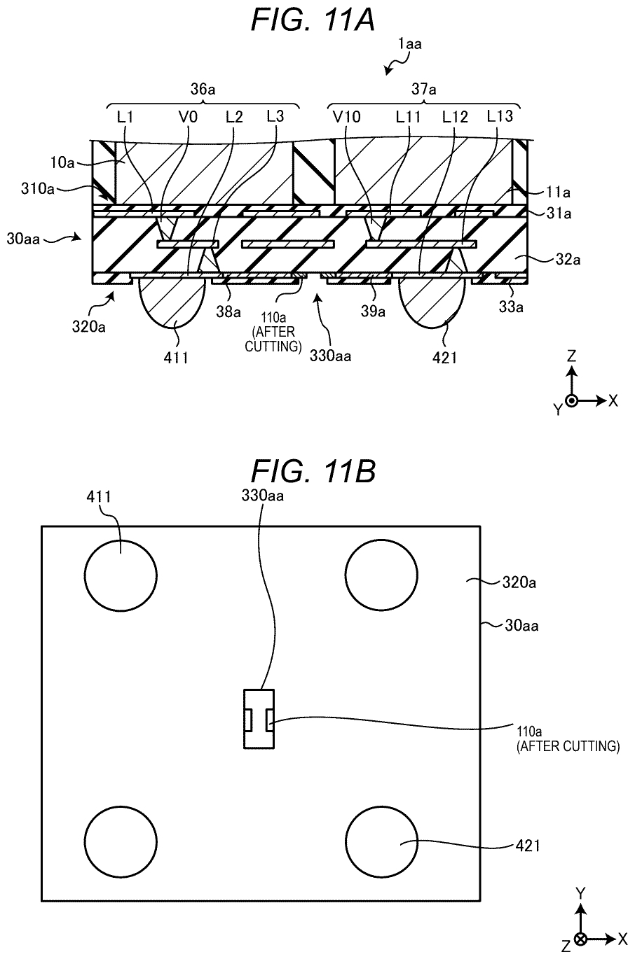

Next, a method of manufacturing a semiconductor system SB including a method of manufacturing the semiconductor device 1aa according to Embodiment 2 will be described with reference to FIGS. 10 and 11.

First, the method of manufacturing the semiconductor device 1aa will be described with reference to FIGS. 10A to 10D. The manufacturing step of the semiconductor device 1aa shown in FIGS. 10A to 10D is performed as a part of the manufacturing step of the semiconductor system SB.

FIGS. 10A to 10D are views sequentially showing a part of the procedure of the method of manufacturing the semiconductor device 1aa according to Embodiment 2. Meanwhile, in FIGS. 10A to 10D, among the manufacturing step of the semiconductor device 1aa, the steps related to the formation of the wiring substrate 30aa will be mainly described. Therefore, the description of a part of steps of the manufacturing steps of the first semiconductor module 10a and the second semiconductor module 11a may be omitted.

As shown in FIG. 10A, the first signal line 36a and the second signal line 37a are formed on the wiring substrate 30aa.

As shown in FIG. 10B, the third signal line 38a connected to the first signal line 36a and the fourth signal line 39a connected to the second signal line 37a are formed. The crosslinking wiring 110a that connects the end portion 381aa of the third signal line 38a and the end portion 391aa of the fourth signal line 39a is formed.

As shown in FIG. 10C, the surface 320a is covered with the solder resist layer 33a. At this time, the opening 330aa for exposing the crosslinking wiring 110a and the opening 360a for forming the first electrode 411 and the second electrode 421 are formed in the solder resist layer 33a.

As shown in FIG. 10D, the first electrode 411 and the second electrode 421 are formed in the opening 360a. Consequently, the manufacturing of the semiconductor device 1aa according to Embodiment 1 is completed.

When the above-described first specification is required, in the manufacturing step of the semiconductor system SB, a process of cutting the crosslinking wiring 110a that connects the crosslinking terminals 382aa and 392aa of the semiconductor device 1aa is performed. The process of cutting the crosslinking wiring 110a is performed after it is determined that the first specification is adapted, that is, immediately before the semiconductor device 1aa is mounted on the mounting substrate 2aa.

FIGS. 11A and 11B are views showing a detailed configuration of the semiconductor device 1aa according to Embodiment 2, and are views showing the state after being diverted from a second specification to a first specification. FIG. 11A is an enlarged cross-sectional view of the semiconductor device 1a corresponding to FIG. 9A, and FIG. 11B is an enlarged plan view of the semiconductor device 1aa corresponding to FIG. 9B.

As shown in FIGS. 11A and 11B, a central portion of the crosslinking wiring 110a that connects the end portion 381aa of the third signal line 38a and the end portion 391aa of the fourth signal line 39a is cut by, for example, dry etching. As a result, the third signal line 38a and the fourth signal line 39a are separated from each other, and the first signal line 36a and the second signal line 37a are electrically separated from each other.

Next, although not shown, the semiconductor device 1aa in which the crosslinking wiring 110a is cut is mounted on the mounting substrate 2aa. As a result, the first signal input and output from the semiconductor device 1b is input and output to and from the first semiconductor module 10a through the first signal line 36a, and the second signal is input and output to and from the second semiconductor module 11a through the second signal line 37a. That is, different signals are individually input and output to and from the semiconductor device 1b to each of the first semiconductor module 10a and the second semiconductor module 11a. Consequently, the manufacturing of the semiconductor system SB according to Embodiment 2 is completed.

### Overview

The semiconductor device 1aa according to Embodiment 2 is provided with the wiring substrate 30aa having the first signal line 36a, the second signal line 37a, the third signal line 38a connected to the first signal line 36a and having an end portion reaching the surface 320a, and the fourth signal line 39a connected to the second signal line 37a and having an end portion reaching the surface 320a. The first signal line 36a and the second signal line 37a input and output the first signal to and from the first semiconductor module 10a and the second semiconductor module 11a. The semiconductor device 1aa is provided with the crosslinking wiring 110a that connects an end portion 381aa of the third signal line 38a and an end portion 391aa of the fourth signal line 39a.

As a result, for example, immediately before the semiconductor device 1a is mounted on the mounting substrate 2a, the crosslinking wiring 110a that connects the end portion 381a and the end portion 391a drawn out to the surface 320a can be cut, and the first signal line 36a and the second signal line 37a can be electrically separated from each other, as necessary. As a result, the semiconductor device 1aa for the second specification can be diverted to the semiconductor device 1aa for the first specification. That is, the generality of the semiconductor device 1aa with respect to the design of the semiconductor system SA is increased.

### Modification Example

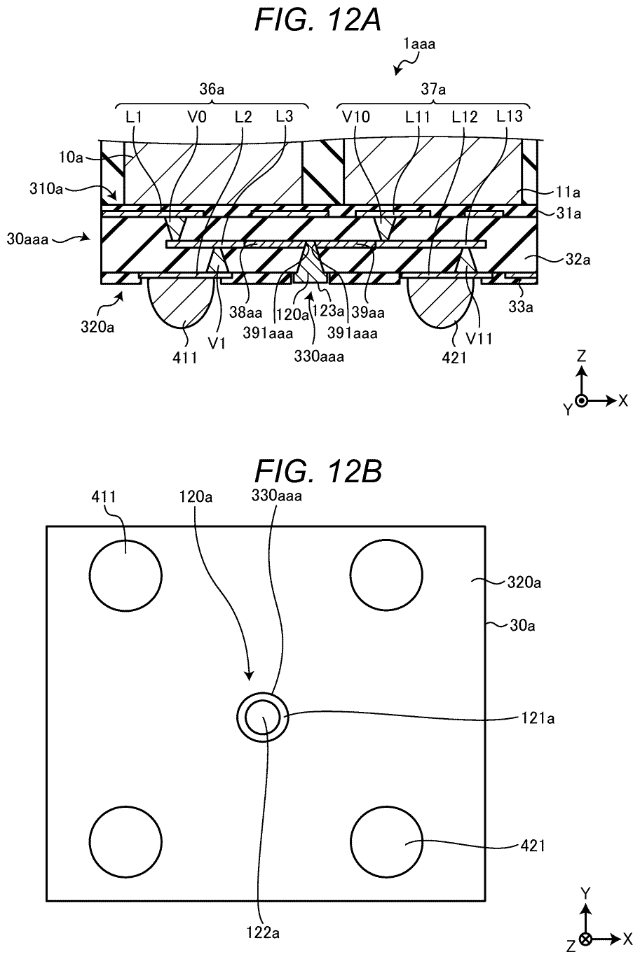

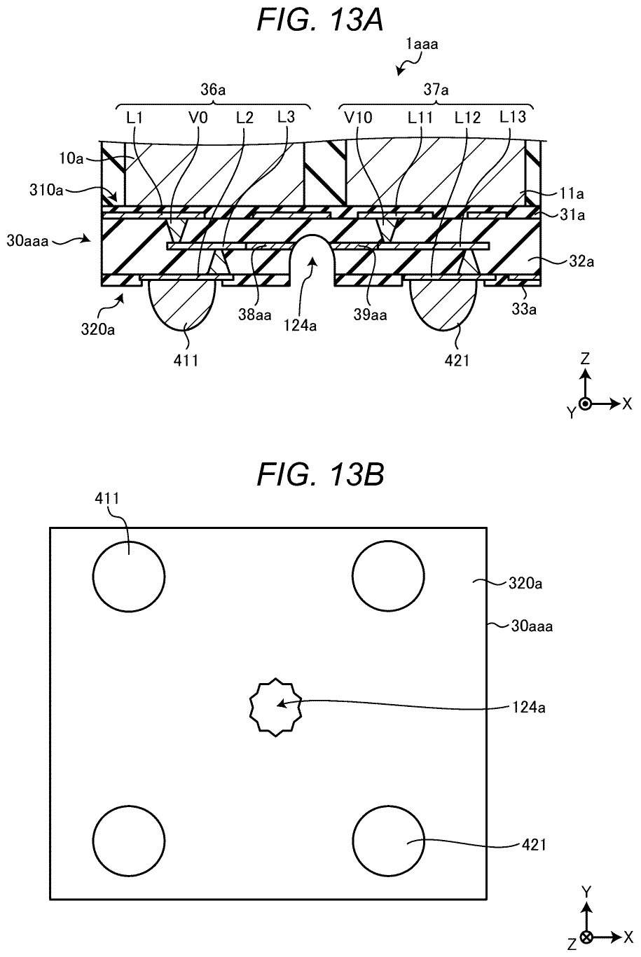

FIGS. 12A to 13B are views showing a modification example according to Embodiment 2.

In a modification example according to Embodiment 2, a configuration of a crosslinking wiring is different from that of Embodiment 2. In the following, the same reference numeral is attached to the same configuration as that in the above-described embodiment, and the description thereof may be omitted.

FIGS. 12A, 12B, 13A, and 13B are views showing a detailed configuration of a semiconductor device 1aaa according to the modification example according to Embodiment 2. More specifically, FIGS. 12A and 13A are enlarged cross-sectional views of the semiconductor device 1aaa corresponding to FIG. 11A, and FIGS. 12B and 13B are enlarged plan views of the semiconductor device 1aaa corresponding to FIG. 11B.

FIGS. 12A and 12B are views showing the state of the semiconductor device 1aaa before being mounted on the mounting substrate 2a.

As described above, the wiring substrate 30aaa is provided with the core layer 32a, the first signal line 36a and the second signal line 37a extending in the core layer 32a, and the solder resist layers 31a and 33a.

The first conductive layer 36a is provided with the wiring layers L1 to L3 and the via layers V0 to V1, and the second conductive layer 37a is provided with the wiring layers L11 to L13 and the via layers V10 to V11.

As shown in FIG. 12A, the third signal line 38aa is connected to the wiring layer L3 and extends in the core layer 32a in the positive X direction. The fourth signal line 39aa is connected to the wiring layer L13 and extends in the core layer 32a in the negative X direction.

An end portion 381aaa of the third signal line 38aa and an end portion 391aaa of the fourth signal line 39aa are connected to each other through a crosslinking via 120a. The end portion 381aaa of the third signal line 38aa is the other end portion of a connection end of the wiring layer L3, and the end portion 391aaa of the fourth signal line 39aa is the other end portion of a connection end of the wiring layer L13. The crosslinking via 120a extends in the core layer 32a in the negative Z direction, and an end portion 123a is exposed to an opening 330aaa of the solder resist layer 33a.

Specifically, as shown in FIG. 12B, the crosslinking via 120a includes a conductive layer 121a formed with a conductive member such as Cu and an insulating layer 122a formed on the inside of the conductive layer 121a. The end portion 381aaa of the third signal line 38aa and the end portion 391aaa of the fourth signal line 39aa are connected to the conductive layer 121a, and thus the third signal line 38aa and the fourth signal line 39aa are electrically connected to each other.

As described above in the description of Embodiment 2, when the semiconductor device 1aaa configured to be applicable to the second specification is required to be diverted to the first specification, the process of cutting the crosslinking via 120a of the semiconductor device 1aaa is performed. The process of cutting the crosslinking via 120a is performed after it is determined that the first specification is adapted, that is, before the semiconductor device 1aaa is mounted on the mounting substrate 2a.

FIGS. 13A and 13B are views showing the state of the semiconductor device 1aaa immediately before being mounted on the mounting substrate 2a.

As shown in FIGS. 13A and 13B, the crosslinking via 120a that connects the end portion 381aaa of the third signal line 38a and the end portion 391aaa of the fourth signal line 39a is cut by, for example, a back drill. As a result, the third signal line 38aa and the fourth signal line 39aa are electrically separated from each other, and the first signal line 36a and the second signal line 37a are electrically separated from each other. A recessed portion 124a extending in the wiring substrate 30aaa in the Z direction is formed in a portion where the crosslinking via 120a is cut.

### Another Modification Example

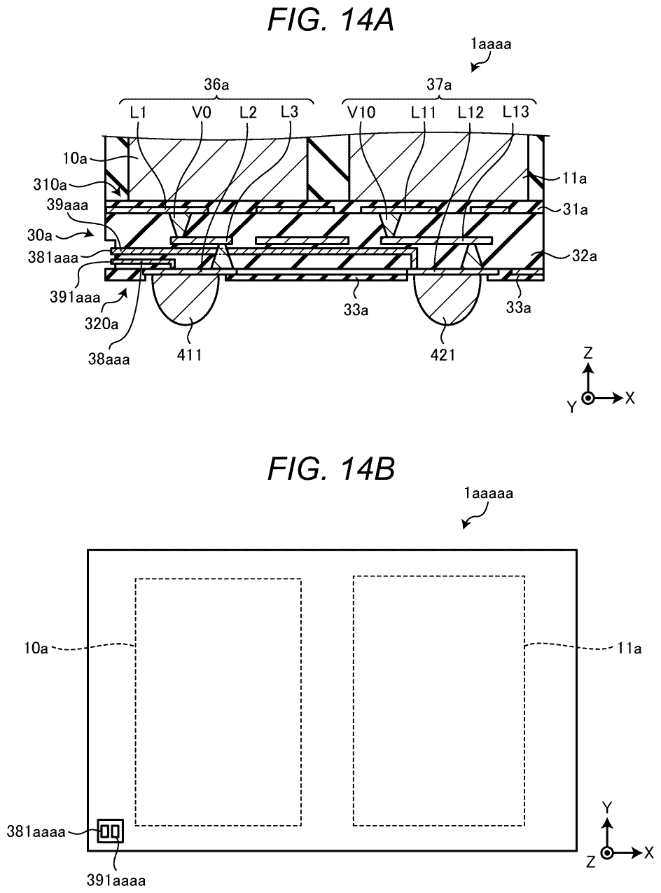

FIGS. 14A and 14B are views showing another modification example.

Each of FIGS. 14A and 14B shows a semiconductor device in a state where the crosslinking wiring is not provided. FIG. 14A is an enlarged cross-sectional view of a semiconductor device 1aaaa, and FIG. 14B is a plan view of a semiconductor device 1aaaaa when viewed from the positive Z direction (upper surface side of the semiconductor device 1aaaaa).

For example, as shown in FIG. 14A, the end portion 381aaa of the third signal line 38aaa and the end portion 391aaa of the fourth signal line 39aaa may reach the side surface of the wiring substrate 30a of the semiconductor device 1aaaa. A crosslinking wiring that connects the end portion 381aaa and the end portion 391aaa may be formed on the side surface of the wiring substrate 30a. Since a dense configuration such as a ball grid array is not provided on the side surface of the wiring substrate 30a, the formation and cutting of the crosslinking wiring can be easily performed. The side surface of the wiring substrate 30a is an example of a third surface.

Alternatively, as shown in FIG. 14B, the end portion 381aaaa and the end portion 391aaaa may reach the upper surface of the semiconductor device 1aaaaa. A crosslinking wiring that connects the end portion 381aaaa and the end portion 391aaaa may be formed on the upper surface of the semiconductor device 1aaaaa. Since a configuration such as a ball grid array is not provided on the upper surface of the semiconductor device 1aaaaa, the formation and cutting of the crosslinking wiring can be easily performed. The upper surface of the semiconductor device 1aaaaa is an example of a third surface.

In the above-described embodiment, an example in which the semiconductor device 1a and the semiconductor device 1b are mounted one by one on the mounting substrate 2 in the semiconductor system has been described, but the present disclosure is not limited thereto. For example, the number of the semiconductor devices 1a mounted on the mounting substrate 2 is any of two, four, eight, or the like.

After cutting the crosslinking wiring 110a, a residual portion of the crosslinking wiring 110a may remain on portions of the third signal line 38a and the fourth signal line 39a. If the crosslinking wiring 110a was formed by a conductive member by ink jet method, residual portions of the conductive member may remain at portions of the third signal line 38a and the fourth signal line 39a. If the crosslinking wiring 110a was formed by bonding wire, residual portions of the bonding wire may remain at portions of the third signal line 38a and a portion of the fourth signal line 39a. If the crosslinking wiring 110a was formed by passive components, residual portions of passive components may remain at portions of the third signal line 38a and the fourth signal line 39a. These residual portions may be different from the material of the portions of the third signal line 38a and the fourth signal line 39a.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first semiconductor module and a second semiconductor module each having one or more semiconductor chips stacked;
a wiring substrate including the first and the second semiconductor modules mounted on a first surface, a first signal line connecting a first electrode provided on a second surface opposite to the first surface to the first semiconductor module, a second signal line connecting a second electrode provided on the second surface to the second semiconductor module, a third signal line connected to the first signal line and having a portion exposed to a third surface, and a fourth signal line connected to the second signal line and having a portion exposed to the third surface; and
a crosslinking wiring that connects the portions of the third and the fourth signal lines to each other, wherein
a first signal is input to or output from at least one of the first semiconductor module or the second semiconductor module through the first and second signal lines.

2. The semiconductor device according to claim 1, wherein
the portions of the third and fourth signal lines are exposed at a position on the third surface that is on a line connecting the first and second electrodes with a shortest distance.

3. The semiconductor device according to claim 1, wherein
the crosslinking wiring includes a conductive member ejected from an ink jet head.

4. The semiconductor device according to claim 1, wherein
the crosslinking wiring is a bonding wire.

5. The semiconductor device according to claim 1, wherein
the crosslinking wiring is a passive component.

6. The semiconductor device according to claim 1, wherein
the third surface is the second surface of the wiring substrate.

7. The semiconductor device according to claim 1, wherein
the wiring substrate further includes an insulating layer provided on a third surface side of the wiring substrate, and the portions of the third and fourth signal lines have openings exposed from the insulating layer.

8. A semiconductor device comprising:
a first semiconductor module and a second semiconductor module each having one or more semiconductor chips stacked thereon; and
a wiring substrate including the first and the second semiconductor modules mounted on a first surface, a first signal line connecting a first electrode provided on a second surface opposite to the first surface to the first semiconductor module, a second signal line connecting a second electrode provided on the second surface to the second semiconductor module, a third signal line connected to the first signal line, a fourth signal line connected to the second signal line, and a crosslinking via connected to portions of the third and fourth signal lines, and having an end portion exposed to a third surface, wherein
a first signal is input to or output from at least one of the first second semiconductor module or the second semiconductor module through the first and second signal lines.

9. A semiconductor device comprising:
a first semiconductor module and a second semiconductor module each having one or more semiconductor chips stacked;
a wiring substrate including the first and the second semiconductor modules mounted on a first surface, a first signal line connecting a first electrode provided on a second surface opposite to the first surface to the first semiconductor module, a second signal line connecting a second electrode provided on the second surface to the second semiconductor module, a third signal line connected to the first signal line and having a portion exposed to a third surface, and a fourth signal line connected to the second signal line and having a portion exposed to the third surface; and
wherein
the portions of the third and fourth signal lines are exposed at a position on the third surface that is on a line connecting the first and second electrodes with a shortest distance,
a first signal is input to or output from the first semiconductor module through the first signal line,
a second signal is input to or output from the second semiconductor module through the second signal line.

10. The semiconductor device according to claim 9, wherein the third surface is the second surface of the wiring substrate.

11. The semiconductor device according to claim 9,
wherein
the wiring substrate further includes an insulating layer provided on a third surface side of the wiring substrate, and the portions of the third and fourth signal lines have openings exposed from the insulating layer.

12. The semiconductor device according to claim 9, further comprising;
a first residual portion formed on the portion of the third signal line; and
a second residual portion formed on the portion of the fourth signal line.

13. The semiconductor device according to claim 12, wherein the first residual portion includes a different material from the portion of the third signal line, and the second residual portion includes a different material from the portion of the fourth signal line.
